(19) United States
(12) Patent Application Publication
(10) Pub. No.: US 2021/0271735 A1
(43) Pub. Date: Sep. 2, 2021

(54) INFORMATION PROCESSING DEVICE, TENSOR COMPRESSION METHOD, AND NON-TRANSITORY COMPUTER READABLE MEDIUM STORING PROGRAM

(71) Applicant: NEC Corporation, Minato-ku, Tokyo (JP)

(72) Inventors: Keigo KIMURA, Tokyo (JP); Yoichi SASAKI, Tokyo (JP)

(73) Assignee: NEC Corporation, Minato-ku, Tokyo (JP)

(21) Appl. No.: 17/257,663

(22) PCT Filed: Jul. 3, 2018
(86) PCT No.: PCT/JP2018/025140

§ 371 Date: Jan. 4, 2021

(51) Int. Cl. G06F 17/16; G06F 7/523; H03M 7/30

(52) U.S. Cl. CPC G06F 17/16; H03M 7/30; G06F 7/523

(57) ABSTRACT

Provided is an information processing device capable of reducing the amount of data of a tensor. An information processing device (1) includes a CSF design unit (11) that sets an order of axes of a tensor of M (M is a natural number of 3 or more) or higher order in order to convert a tensor into data in CSF (Compressed Sparse Fiber) representation, a CSF construction unit (12) that converts the tensor of M or higher order into data in CSF representation according to setting by the CSF setting unit (11), and a CSF compression unit (13) that compresses the data in CSF representation by replacing an overlapping structure appearing in the data in CSF representation with an alternative structure representing the overlapping structure, and outputs compressed CSF data being a compressed version of the data in CSF representation and replacement rule data being data indicating a replacement rule.

### TECHNICAL FIELD

The present disclosure relates to an information processing device, a tensor compression method, and a program.

### BACKGROUND ART

A tensor (multidimensional array) is increasingly used as a data representation with the recent improvement in data collection technology and improvement in computer performance.

A tensor is a multidimensional array, and it may be regarded as a generalization of a matrix. A matrix can represent only a binary relation between documents and terms, such as a document-term matrix, for example. On the other hand, a tensor can represent a ternary relation such as document-term-time. In this manner, a tensor is able to represent more information than a matrix. Thus, studies are conducted in the field of machine learning and data mining.

However, the mining of data represented by a tensor requires an extremely long computation time. For example, in a technique called tensor decomposition that decomposes a tensor into a plurality of matrix products, the product of a tensor and a plurality of matrices (all matrices other than the matrix to be optimized) is needed for the optimization of each matrix. This is an extremely large amount of computation.

An operation that requires a large amount of computation in the tensor decomposition is the following tensor-matrix multiplication.

$${P}_{{i}_{n} j} = {Σ}_{{i}_{1} , . . . , {i}_{n - 1} . . . , {i}_{n + 1} , . . . , {i}_{M}} {X}_{{i}_{1} , . . . , {i}_{n - 1} . . . , {i}_{n + 1} , . . . , {i}_{M}} * {N}_{{i}_{1} j}^{( 1 )} * . . . {N}_{{i}_{n - 1} j}^{( n - 1 )} * {N}_{{i}_{n + 1} j}^{( n + 1 )} * . . . * {N}_{{i}_{M} j}^{( M )} \qquad Expression ( 1 )$$

Expression (1) shows a tensor-matrix multiplication for an M-order tensor. N^{(k)} is a matrix obtained by tensor decomposition.

This calculation is needed for the computation of a gradient that is used when optimizing N^{(k)}, and it is necessary to perform the calculation for all in and j and obtain P.

Note that, in Expression (1), the matrix P is a matrix indicating a calculation result of the tensor-matrix multiplication, which is, a matrix storing a calculation result of the tensor-matrix multiplication. In other words, the matrix P is obtained as a calculation result of the tensor-matrix multiplication. Expression (1) is an expression indicating a calculation method for each element of P. Further, X is a tensor. j and in indicate indices of elements. n indicates an axis of a tensor. For example, in the case of a second-order tensor (i.e., matrix), n=1 indicates a row, and n=2 indicates a column. In the case of a third-order tensor, n=3 indicates a depth.

Further, a recent increase in tensor size causes a problem that a tensor cannot be stored in a memory, and computation by an in-memory process cannot be done. This is because non-zero elements in a tensor require indices corresponding to the axes of the tensor. For example, a fourth-order tensor needs to have indices (i,j,k,l). Its memory usage is twice that of a matrix having (i,j) components only.

In regards to this problem, Non Patent Literature 1 proposes a CSF (Compressed Sparse Fiber) representation that reduces the size of a tensor by representing the indices of non-zero elements in the tensor by a tree structure, and a tensor-matrix multiplication algorithm using this tree structure. By the tree structure, some computations are omitted in the tensor-matrix multiplication. However, this is mainly applicable to the calculation for leaf nodes only, and calculations are not omitted in many cases.

In the technique disclosed in Patent Literature 1, memory reduction and higher-speed computation are achieved by storing non-zero elements only and representing data in a plurality of matrix forms for efficient computation of a tensor-matrix multiplication. However, since memory reduction is achieved by storing non-zero elements only, the technique is hardly applicable to a tensor with an enormous number of non-zero elements. Further, since it is necessary to use overlapping representations, a larger computational space is needed compared with the case of simply representing non-zero elements only.

Patent Literature 2 is a technique using the tensor decomposition as compression. However, this technique is based on the assumption that the tensor decomposition is feasible. Further, a loss of information occurs in the tensor decomposition, which can cause a decrease in the accuracy of a task after compression.

### CITATION LIST

### Patent Literature

PTL1: Japanese Unexamined Patent Application Publication No. 2016-139391
PTL2: Published Japanese Translation of PCT International Publication for Patent Application, No. 2005-514683

### Non Patent Literature

NPL1: Smith, S., Ravindran, N., Sidiropoulos, N. D., & Karypis, G. “SPLATT: Efficient and parallel sparse tensor-matrix multiplication”, In 2015 IEEE International Parallel and Distributed Processing Symposium (IPDPS), pp. 61-70, May 2015.

### SUMMARY OF INVENTION

### Technical Problem

Thus, there is still a demand for a novel technique to achieve storing a tensor in a memory.

An object of the present disclosure is to provide an information processing device, a tensor compression method, and a program capable of reducing the amount of data of a tensor.

### Solution to Problem

An information processing device according to the present disclosure includes a CSF setting unit configured to set an order of axes of a tensor of M (M is a natural number of 3 or more) or higher order in order to convert a tensor into data in CSF (Compressed Sparse Fiber) representation, a CSF construction unit configured to convert the tensor of M or higher order into data in CSF representation according to setting by the CSF setting unit, and a CSF compression unit configured to compress the data in CSF representation by replacing an overlapping structure appearing in the data in CSF representation with an alternative structure representing the overlapping structure, and output compressed CSF data being a compressed version of the data in CSF representation and replacement rule data being data indicating a replacement rule.

A tensor compression method according to the present disclosure includes setting an order of axes of a tensor of M (M is a natural number of 3 or more) or higher order in order to convert a tensor into data in CSF (Compressed Sparse Fiber) representation, converting the tensor of M or higher order into data in CSF representation according to the setting, and compressing the data in CSF representation by replacing an overlapping structure appearing in the data in CSF representation with an alternative structure representing the overlapping structure, and outputting compressed CSF data being a compressed version of the data in CSF representation and replacement rule data being data indicating a replacement rule.

A program according to the present disclosure causes a computer to perform a CSF setting step of setting an order of axes of a tensor of M (M is a natural number of 3 or more) or higher order in order to convert a tensor into data in CSF (Compressed Sparse Fiber) representation, a CSF construction step of converting the tensor of M or higher order into data in CSF representation according to setting in the CSF setting step, and a CSF compression step of compressing the data in CSF representation by replacing an overlapping structure appearing in the data in CSF representation with an alternative structure representing the overlapping structure, and outputting compressed CSF data being a compressed version of the data in CSF representation and replacement rule data being data indicating a replacement rule.

### Advantageous Effects of Invention

According to the present disclosure, there are provided an information processing device, a tensor compression method, and a program capable of reducing the amount of data of a tensor.

### BRIEF DESCRIPTION OF DRAWINGS

FIG. 1 is a block diagram showing a configuration example of an information processing device according to a first example embodiment.

FIG. 2 is a view showing an example of a CSF.

FIG. 3 is a view showing a hardware configuration of an information processing device according to the first example embodiment and a second example embodiment.

FIG. 4 is a flowchart showing the operation of a tensor compression device according to the first example embodiment.

FIG. 5 is a view showing an example of replacement of frequently-appearing substructures in a CSF.

FIG. 6 is a block diagram showing a configuration example of a compressed tensor-matrix multiplication device according to the second example embodiment.

FIG. 7 is a flowchart showing an operation example of the compressed tensor-matrix multiplication device according to the second example embodiment.

### DESCRIPTION OF EMBODIMENTS

Example embodiments of the present disclosure will be described hereinafter with reference to the drawings. In the figures, the identical reference symbols denote identical structural elements and the redundant explanation thereof is omitted.

### First Example Embodiment

### <Description of Configuration>

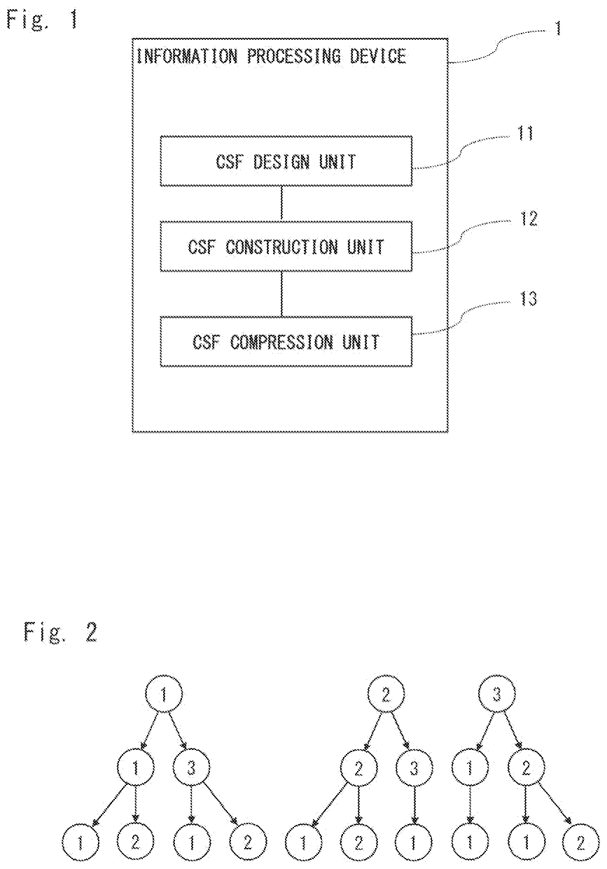

FIG. 1 is a block diagram showing the configuration of an information processing device 1, which serves as a tensor compression device, according to a first example embodiment. FIG. 2 is a view showing an example of a CSF. In the tree structure shown in FIG. 2, each axis corresponds to the order of a tensor, and a node label (number shown in each node) indicates an index of non-zero elements in a tensor. As shown in FIG. 1, the information processing device 1 as the tensor compression device includes a CSF design unit 11, a CSF construction unit 12, and a CSF compression unit 13.

The CSF design unit 11 sets a CSF construction method as preprocessing for constructing a CSF that represents non-zero element indices in a tensor of M or higher order. In the CSF, the depth of the tree corresponds to axes as shown in FIG. 2. For example, when the number of axes is three, the construction of a CSF composed of a node with depth 0, a node with depth 1, and a node with depth 2 is possible as shown in FIG. 2. Specifically, there are CSF construction methods corresponding to the number of combinations of axes. Thus, to be specific, the CSF design unit 11 sets the combination order of axes of the CSF. For the order of setting the axes, an arbitrary method by a user may be used. For example, it may be a previously input order of axes of a tensor or may be an order obtained by sorting the dimensions of axes in ascending order. In this manner, the CSF design unit 11 sets the order of axes of a tensor of M (M is a natural number of 3 or more) or higher order in order to convert a tensor into data in CSF representation. Note that the CSF design unit 11 may be referred to as a CSF setting unit.

The CSF construction unit 12 constructs a CSF based on the indices of non-zero elements in the tensor, which is input, by using the order of axes in the construction of the CSF that is set by the CSF design unit 11. The structure of a CSF is uniquely determined once the order of axes is fixed. Thus, the construction may be done in any way. For example, the CSF construction unit 12 constructs a CSF by the technique disclosed in the above-described Non Patent Literature 1. In this manner, the CSF construction unit 12 converts a tensor of M or higher order into data in CSF representation according to the setting by the CSF design unit 11.

The CSF compression unit 13 compresses the CSF constructed by the CSF construction unit 12. For the compression of a CSF, a compression method that replaces frequently-appearing substructures is used. A compression method called grammar compression is one example of such a replacement method. The grammar compression is a compression method that achieves a high compression rate by having an auxiliary data structure called a dictionary, separately from a compressed result, and describing a replacement method in this dictionary. The CSF compression unit 13 can use another known technique, not limited to the grammar compression. Note that, however, it is desirable to use a compression method of performing compression that completely restores information by using a dictionary, though not limited thereto. The frequently-appearing substructure is a subtree that appears a predetermined number of times or more (at least two or more times) in a CSF tree structure. The frequently-appearing substructure may be referred to as an overlapping structure. In this manner, the CSF compression unit 13 compresses data in CSF representation by replacing the overlapping structure that appears in the data in CSF representation with an alternative structure representing this overlapping structure. Then, the CSF compression unit 13 outputs compressed CSF data, which is compressed data in CSF representation, and replacement rule data (dictionary), which is data indicating a replacement rule.

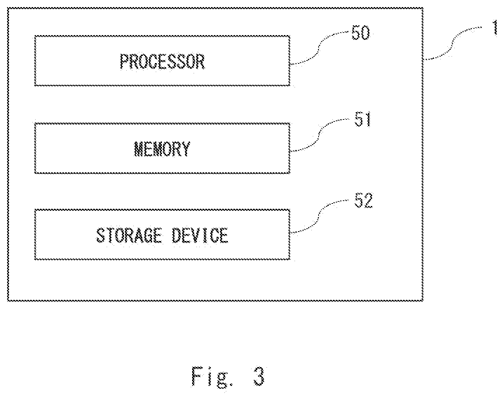

Note that the information processing device 1 includes a processor 50, a memory 51, and a storage device 52 as shown in FIG. 3, for example, and thereby performs processing. The processor 50 may be a microprocessor, an MPU (Micro Processing Unit), a CPU (Central Processing Unit) or the like, for example. The memory 51 is a memory composed of a volatile memory or a nonvolatile memory, for example. The storage device 52 is a storage such as a hard disk drive, a solid-state drive or the like, for example.

The storage device 52 stores a computer program containing one or more instructions for implementing each of the elements shown in FIG. 1. The processor 50 reads a computer program from the storage device 52 into the memory 51 and executes this computer program. The processor 50 thereby implements the functions of the CSF design unit 11, the CSF construction unit 12, and the CSF compression unit 13.

The above-described program can be stored and provided to the computer using any type of non-transitory computer readable medium. The non-transitory computer readable medium includes any type of tangible storage medium. Examples of the non-transitory computer readable medium include magnetic storage media (such as floppy disks, magnetic tapes, hard disk drives, etc.), optical magnetic storage media (e.g. magneto-optical disks), CD-ROM (Read Only Memory), CD-R, CD-R/W, and semiconductor memories (such as mask ROM, PROM (Programmable ROM), EPROM (Erasable PROM), flash ROM, RAM (Random Access Memory), etc.). The program may be provided to a computer using any type of transitory computer readable medium. Examples of the transitory computer readable medium include electric signals, optical signals, and electromagnetic waves. The transitory computer readable medium can provide the program to a computer via a wired communication line such as an electric wire or optical fiber or a wireless communication line.

The information processing device 1 performs compression on a tensor previously stored in the storage device 52 (i.e., data of a tensor before compression), for example. The information processing device 1 may store the tensor compressed by the CSF compression unit 13 and a dictionary, which is an auxiliary data structure, into the memory 51 or output them to a device outside the information processing device 1.

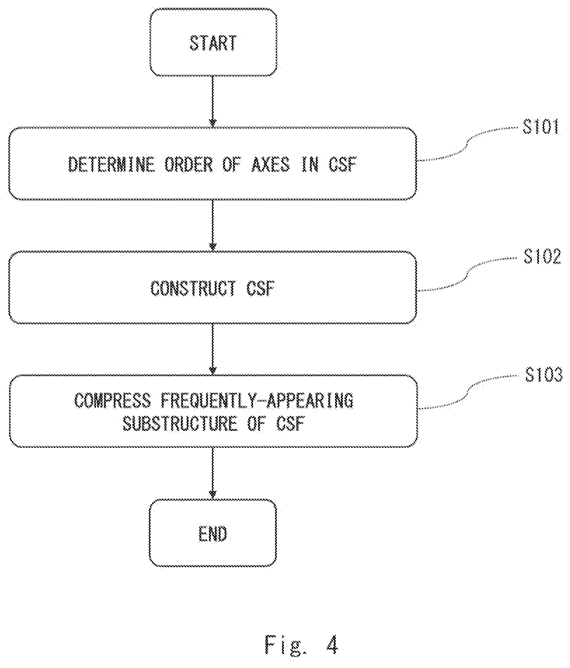

FIG. 4 is a flowchart showing the flow of a tensor compression method that is performed by the information processing device 1 according to the first example embodiment. First, the CSF design unit 11 receives all indices of non-zero elements in an M-order tensor, and determines the order of axes of the CSF by a predetermined standard (Step S101). Next, the CSF construction unit 12 constructs a CSF from the non-zero elements in the M-order tensor based on the CSF structure (i.e., the order of axes) obtained by the CSF design unit 11 (Step S102). Then, the CSF compression unit 13 compresses frequently-appearing substructures of the CSF constructed by the CSF construction unit 12 by a predetermined compression method (Step S103).

As described above, the compression of a tensor is achieved by this example embodiment. Specifically, a data representation is made by using a compressed CSF representation and a dictionary, which is an auxiliary data structure, without directly using a CSF representation of a tensor.

A tensor to which this example embodiment is applicable is data called a knowledge graph, for example. The knowledge graph is represented by a triplet of subject, predicate, and object. When the subject is the predicate of the object, it has 1. When the subject is not the predicate of the object, it has 0. Thus, the knowledge graph is represented by a third-order tensor, where the subject, the predicate, and the object are the respective axes, by giving indices. Therefore, the information processing device 1 according to this example embodiment can be also called a knowledge graph compression device.

### Specific Example 1

The operation of the information processing device 1 as the tensor compression device according to the first example embodiment is described hereinafter by using a specific example.

First, assume that non-zero element indices of a tensor to be compressed are as follows. Assume also that the size of the tensor is (2,3,3).

$$( \begin{matrix}1 & 1 & 1 \\ 1 & 1 & 3 \\ 1 & 2 & 2 \\ 1 & 2 & 3 \\ 1 & 3 & 1 \\ 1 & 3 & 2 \\ 2 & 1 & 1 \\ 2 & 2 & 2 \\ 2 & 2 & 3 \\ 2 & 3 & 1\end{matrix} ) \qquad Expression ( 2 )$$

The CSF design unit 11 determines the structure of construction, which is the order of axes, by an arbitrary standard. In this specific example, the order of axes where the dimensions of axes are sorted in descending order is adopted. In the CSF, as the depth of a tree is lower, an index is shared and represented by one node at an intermediate node or a root node. Thus, as the variety of indices is smaller, the indices are more likely to be shared. Thus, memory usage required for a CSF representation is likely to be reduced.

Therefore, in the case of the tensor represented by Expression (2), 3-2-1 (or 2-3-1) is selected as the structure of the CSF. Note that 3-2-1 indicates the order of axes: the axis corresponding to the indices described in the third column from the left in Expression (2), the axis corresponding to the indices described in the second column from the left, and the axis corresponding to the indices described in the first column from the left.

Next, the CSF construction unit 12 constructs the CSF as shown in FIG. 2 from the structure 3-2-1 selected by the CSF design unit 11 and the tensor in Expression (2).

Then, the CSF compression unit 13 compresses the CSF constructed by the CSF construction unit 12. In this description, a technique of replacing only a frequently-appearing substructure at a leaf node is described for easier understanding.

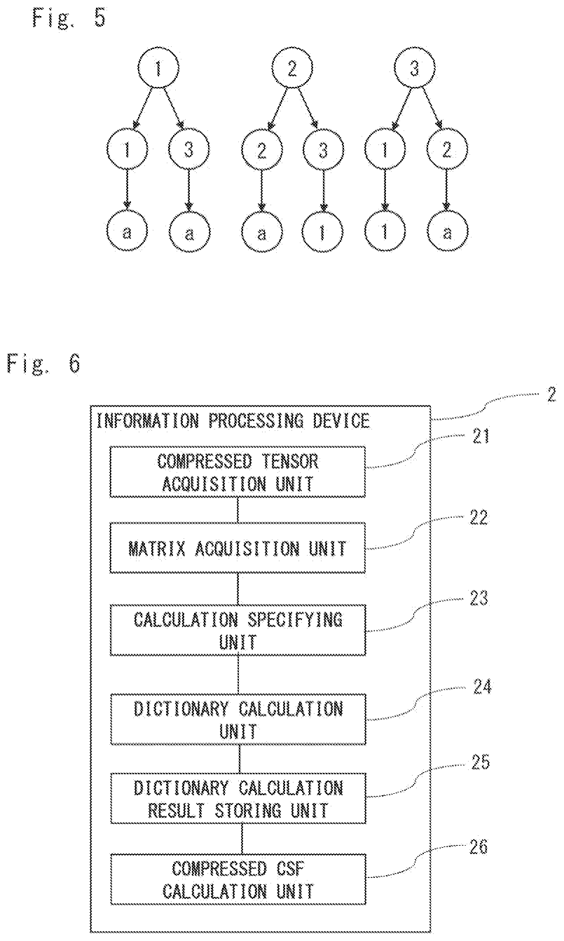

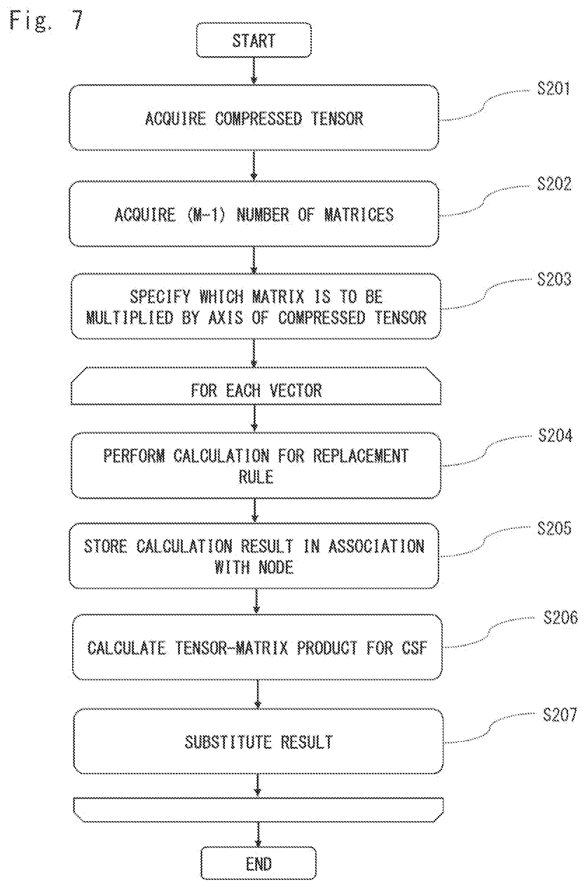

The frequently-appearing substructure at a leaf node of the CSF shown in FIG. 2 is the simultaneous appearance of the label “1” and the label “2”. Thus, the CSF compression unit 13 replaces this substructure with a new node with the label “a”. The new CSF as shown in FIG. 5 is thereby obtained. This is the compressed CSF. Then, information about replacement, which is, data indicating a replacement rule (replacement rule data) is stored in the dictionary as follows.

a→[1,2] Expression (3)

Two nodes are thereby replaced with one node. Since this replacement occurs four times, the number of nodes is compressed from 8 to 4, and since the replacement rule of the dictionary (Expression (3)) can be represented by three numbers (a,1,2), the compression is made from a representation with total eight data to a representation with seven data. Although two nodes are replaced with one node in the above-described example, three or more nodes may be replaced with one node.

The CSF compression unit 13 lists all frequently-appearing substructures and carries out replacement only when the entire number of data is reduced by the replacement. After the replacement, the CSF compression unit 13 lists frequently-appearing substructures again and replaces the frequently-appearing substructure where the entire number of data is reduced by the replacement again. This operation is performed until the reduction of the number of data by the replacement cannot be done any more, for example. Although it is preferable to repeat the replacement as much as possible in order for increasing the compression efficiency, the CSF compression unit 13 may end the replacement process in the state where frequently-appearing substructures where the number of data can be reduced remain. The CSF compression unit 13 performs the compression by such processing.

Although an example of replacing only frequently-appearing substructures at leaf nodes is shown in the above description, the compression may be made on arbitrary frequently-appearing substructures including intermediate nodes (i.e. nodes other than root nodes and leaf nodes) and root nodes. In other words, the compression may be carried out also on a subtree. Note that, however, a substructure to be replaced needs to be in the state where no child node is connected to this substructure. This is because the CSF is a multi-branch tree. If a substructure having a child node is replaced, it is not uniquely determined which node is a parent node of this child node before replacement.

The first example embodiment is described above. According to the information processing device 1 according to the first example embodiment, the number of data in a CSF is reduced by the CSF compression unit 13. This allows the amount of data of a tensor to be small. This enables a tensor to be stored in a memory with limited capacity that is mounted on a device that performs specified processing such as machine learning or data analysis by using the tensor, for example.

### Second Example Embodiment

In this example embodiment, an information processing device 2, which serves as a compressed tensor-matrix multiplication device, that calculates the product of a tensor compressed by the tensor compression device according to the first example embodiment and a plurality of matrices is described. Specifically, the compressed tensor-matrix multiplication device that performs the calculation represented by Expression (1) by using a compressed tensor is described in this embodiment.

FIG. 5 is a block diagram showing the configuration of the information processing device 2 as the compressed tensor-matrix multiplication device according to this example embodiment. The information processing device 2 includes a compressed tensor acquisition unit 21, a matrix acquisition unit 22, a calculation specifying unit 23, a dictionary calculation unit 24, a dictionary calculation result storing unit 25, and a compressed CSF calculation unit 26. Note that the information processing device 2 may be an information processing device that includes the information processing device 1 according to the first example embodiment.

The compressed tensor acquisition unit 21 is an element that acquires a tensor compressed by the information processing device 1 as the tensor compression device. To be specific, the compressed tensor acquisition unit 21 acquires a compressed CSF and a dictionary, which is an auxiliary data structure. The compressed tensor acquisition unit 21 reads the compressed CSF and the dictionary stored in the memory 51 or the storage device 52, for example.

The matrix acquisition unit 22 acquires (M−1) number of matrices to be multiplied with the compressed tensor. In other words, the matrix acquisition unit 22 acquires matrices to be used for calculation. The matrix acquisition unit 22 reads the matrices stored in the memory 51 or the storage device 52, for example.

The calculation specifying unit 23 specifies in which axis and in what way the calculation of the (M−1) number of matrices acquired by the matrix acquisition unit 22 is to be performed in the multiplication of a tensor and matrices. Just as the multiplication of matrices requires specifying from which of right and left the multiplication of matrices is to be performed, in the multiplication of a tensor and matrices, it is necessary to specify in which axis direction the multiplication is to be performed. Therefore, it is necessary to previously specify with which matrix and in which axis the multiplication is to be performed. The calculation specifying unit 23 specifies them according to previously set definition information that defines calculations, for example.

The dictionary calculation unit 24 is an element that previously computes a calculation necessary in the calculation of Expression (1) for frequently-appearing substructures replaced according to a dictionary, which is an auxiliary data structure. The dictionary calculation unit 24 performs a calculation (which is referred to hereinafter as a sub-calculation) for calculating a tensor-matrix product by using matrix elements corresponding to the indices indicated by the frequently-appearing substructures before replacement.

The dictionary calculation result storing unit 25 is an element that stores calculation results obtained by calculations in the dictionary calculation unit 24. To be more specific, the dictionary calculation result storing unit 25 stores a calculation result for a frequently-appearing substructure before replacement in association with a new node after replacement. In other words, the dictionary calculation result storing unit 25 stores a result of the sub-calculation on a frequently-appearing substructure before replacement as a result of the sub-calculation on a new node after replacement. Consequently, when a calculation on a new node after replacement is required, the calculation result can be extracted from the dictionary calculation result storing unit 25, which avoids repeating the same computation and thereby reduces the number of computations.

The compressed CSF calculation unit 26 is an element that performs a search and a calculation on the compressed CSF. The compressed CSF calculation unit 26 makes a search sequentially from a root node and performs a calculation on the CSF. The compressed CSF calculation unit 26 performs calculations by changing a calculation method depending on which depth in the CSF an axis not selected as a target of calculation by specification of the calculation specifying unit 23 corresponds to. To be specific, the compressed CSF calculation unit 26 performs a calculation by a predetermined first calculation method when the axis that is not selected corresponds to a root node, performs a calculation by a predetermined second calculation method when it corresponds to a leaf node, and performs a calculation by a predetermined third calculation method when it corresponds to an intermediate node.

FIG. 6 is a flowchart for describing the flow of a compressed tensor-matrix multiplication method that is performed by the information processing device 2 according to the second example embodiment.

First, the compressed tensor acquisition unit 21 acquires a compressed tensor for which a calculation is to be performed (Step S201).

Next, the matrix acquisition unit 22 acquires matrices for which a calculation is to be performed (Step S202).

Then, the calculation specifying unit 23 specifies in which axis and which matrix multiplication is to be performed (Step S203).

After Step S203, the following operations (Step S204 to Step S207) are performed on each column of the matrix, which is, on the j-th vector of P in Expression (1).

First, the dictionary calculation unit 24 performs a sub-calculation for calculating a tensor-matrix product on all frequently-appearing substructures (Step S204).

Then, all calculation results obtained in Step S204 are stored into the dictionary calculation result storing unit 25 in association with new nodes after replacement described in the dictionary (Step S205).

After that, the compressed CSF calculation unit 26 performs calculations on the CSF sequentially from a root node by changing a calculation method depending on which depth in the CSF an axis not selected for calculation by specification of the calculation specifying unit 23 corresponds to (Step S205).

The compressed CSF calculation unit 26 substitutes calculation results in Step S205 into the j-th element in P (Step S207). In other words, the compressed CSF calculation unit 26 stores the calculation results for the j-th vector in P. This series of operations (Step S204 to Step S207) are repeated for each vector until they are performed for all vectors. A compressed tensor-matrix product is obtained as a result of performing the operations of S204 to Step S207 on all vectors.

### Specific Example 2

In this specific example, an example of a calculation by the tensor-matrix multiplication device according to the second example embodiment is described. In this specific example, a calculation on the compressed tensor shown in the specific example 1 is described. In the following description, a generalized matrix is used in order to describe various cases. Further, it is assumed that the number of columns of a matrix is 1 for the sake of simplification. In other words, j=1. Therefore, the same calculation as the tensor-vector multiplication is used in this specific example. Note that, however, this can be easily generalized to the tensor-matrix multiplication since the calculation of each column is the same.

For a tensor-matrix product to be calculated, a different calculation method is required depending on input. Since the input is (M−1) number of matrices, it is always the case that one axis is not to be multiplied by a matrix. A calculation method varies depending on whether this axis n is (1) an axis corresponding to a root node (i.e. n=1), (2) an axis corresponding to a leaf node (i.e. n=M), and (3) an axis corresponding to an intermediate node (i.e. l<n<M).

An index corresponding to the depth of the CSF shown in FIG. 4 is defined as follows. Specifically, assume that the index corresponding to a root node is i₁, the index corresponding to an intermediate node is i₂, and the index corresponding to a leaf node is i₃. Further, the matrix corresponding to the axis corresponding to a root node is A, the matrix corresponding to the axis corresponding to an intermediate node is B, and the matrix corresponding to the axis corresponding to a leaf node is C.

The behavior in the above-described cases (1) to (3) is sequentially described hereinafter for the case where the compressed CSF in FIG. 5 and the dictionary represented by Expression (3) are obtained.

An element calculation of a tensor-matrix product that is calculated in the case (1) is as follows.

Pᵢ_{₁}ⱼ=Σᵢ_{₂}_{,i}_{₃}Xᵢ_{₁}ᵢ_{₂}ᵢ_{₃}*Bᵢ_{₂}ⱼ*Cᵢ_{₃}ⱼ Expression (4):

Since j=1, the description of j is omitted hereinbelow. Further, a tensor is binary in this example. In this specific example, a calculation method of P₁ is described. First, for the replacement rule represented by Expression (3), the dictionary calculation unit 24 performs a calculation corresponding to this replacement rule. In the replacement rule represented by Expression (3), the indices before replacement are “1” and “2”, and the matrix corresponding to a leaf node is C, and therefore a calculation result of the dictionary calculation unit 24 for this replacement rule is (C₁+C₂). Thus, the dictionary calculation result storing unit 25 stores a result a=(C₁+C₂). In this manner, the dictionary calculation result storing unit 25 stores “a” and the calculation result (C₁+C₂) in association with each other.

In order to calculate P₁, the compressed CSF calculation unit 26 performs processing by depth-first search from the corresponding root node, which is a node with label “1” at depth 0 in FIG. 5. First, a search proceeds to a child node on the left, and then proceeds to a node with label “1” at the second level. Then, the search proceeds to a node with label “a”, which is a child node of the node with label “1” at the second level. Since the depth of this node with label “a” is M−1, there is no child node. Therefore, the compressed CSF calculation unit 26 performs processing so that a node returns a value to a parent node. When a node having no child node is a replaced node, a calculation result corresponding to this node is acquired from the dictionary calculation result storing unit 25, and this calculation result is returned to a parent node. Thus, the node with label “1” at the second level receives (C₁+C₂) from the node with label “a”. When a node having a child node returns a value, a calculation result of the product of the element of the matrix corresponding to this node and the sum of results received from all child nodes is returned to a parent node. Since there is no node other than the node with label “a” in this example, B₁(C₁+C₂), which is the product of the element B₁ corresponding to the node with label “1” at the second level and (C₁+C₂) received from child nodes, is returned to a parent node.

The dictionary calculation unit 24 performs a calculation on a called node when n=M is not true. To be specific, as described above, when the node with label “a” is called, the dictionary calculation unit 24 outputs the sum of the element C₁ and the element C₂ as a calculation result in this example because “a” corresponds to the label “1” and the label “2” according to the replacement rule by Expression (3). This calculation corresponds to the calculation in Expression (4) on the node with label “1” and the node with label “2”.

The dictionary calculation result storing unit 25 stores this calculation result as a=(C₁+C₂), and the node with label “1” at the second level obtains (C₁+C₂) as a return value. The compressed CSF calculation unit 26 then performs a calculation of B₁(C₁+C₂). Then, the value of B₁(C₁+C₂) is returned to the node at the first level (depth 0).

Then, the compressed CSF calculation unit 26 performs the same operation on a node with label “3” at the second level, which is a next child node (child node on the right) with label “1” at the first level,

After the search of the node with label “3” at the second level, the search proceeds to a node with label “a” in the same manner. The node with label “a” returns (C₁+C₂), and the node with label “3” at the second level returns B₃(C₁+C₂).

Finally, the compressed CSF calculation unit 26 calculates the sum of results obtained from all child nodes by the node with label “1” at the first level. This calculation result is the same as P₁.

Consider the case where the compression on the label “a” is not done. In this case, each node at the second level receives C₁ and C₂ respectively from child nodes, and C₁+C₂ is computed. Thus, the calculation of C₁+C₂ needs to be performed twice. On the other hand, in the case where the compression on the label “a” is done and a calculation result for the label “a” is stored in the dictionary calculation result storing unit 25, the calculation of C₁+C₂ is performed only once by the dictionary calculation unit 24. Thus, the number of calculations is small in this example embodiment.

An example in the case (2) (when n=M) is described below.

An element calculation of a tensor-matrix product that is calculated in this case is as follows.

Pᵢ_{₃}ⱼ=Σᵢ_{₁}_{,i}_{₂}Xᵢ_{₁}ᵢ_{₂}ᵢ_{₃}*Aᵢ_{₁}ⱼ*Bᵢ_{₂}ⱼ Expression (5):

In this case, there is no improvement in the amount of computation. This is because C₁ and C₂ do not appear in Expression (5). To reduce the amount of computation, the dictionary calculation unit 24 and the dictionary calculation result storing unit 25 may refrain from performing a calculation and storing depending on a designated axis.

In this case also, the compressed CSF calculation unit 26 performs processing by depth-first search in the same manner as in the case (1). However, this case is different from the case (1) in that the compressed CSF calculation unit 26 propagates a value obtained by a search to a child node.

A tree having a node with label “1” at the first level is described hereinafter, just like in the description of the case 1.

First, a node with label “1” at the first level sends A₁, which is an element corresponding to the index indicated by this label, to a node with label “1” at the second level, which is a child node on the left.

Next, the compressed CSF calculation unit 26 multiplies the value B₁ corresponding to the index indicated by the node with label “1” at the second level by the value sent from a parent node. The obtained value A₁*B₁ is sent to a node at the third level (node with label “a”), which is a child node. Since the node at the third level (node with label “a”) is obtained by replacement, the compressed CSF calculation unit 26 performs an operation that adds a value received from parent node to each of elements of the matrix storing calculation results which corresponds to the index of the compressed node. To be specific, the compressed CSF calculation unit 26 performs calculations of P₁+=A₁*B₁ and P₂+=A₁*B₁. Note that the initial values of P₁ and P₂ are 0.

The calculation of Expression (5) is achieved by performing such processing on all nodes at the first level.

Finally, the case (3) is described. This is solvable by combining the case (1) and the case (2).

An element calculation of a tensor-matrix product that is calculated in the case (3) is as follows.

Pᵢ_{₂}ⱼ=Σᵢ_{₁}_{,i}_{₃}Xᵢ_{₁}ᵢ_{₂}ᵢ_{₃}*Aᵢ_{₁}ⱼ*Cᵢ_{₃}ⱼ Expression (6):

In the case (3), the compressed CSF calculation unit 26 performs a calculation by a method that sends values to child nodes in the same way as the behavior in the case (2) until reaching a node at the i-th level where i<n, and at i=n, stores the values obtained by the search and switches to the behavior in the case (1).

To be specific, an example at n=2 is as follows. A calculation method for a tree having a node with label “1” at the first level is described, just like in the description of the case (1) and the case (2).

Since the node with label “1” at the first level is i=1<n=2, the compressed CSF calculation unit 26 performs processing to pass the value A₁ corresponding to this node to a node with label “1” at the second level, which is a child node. Next, the compressed CSF calculation unit 26 performs processing so that the node with label “1” at the second level tentatively stores the value sent from a parent node. Then, the compressed CSF calculation unit 26 continues the search without sending the value to a child node. Just like in the case (1), the compressed CSF calculation unit 26 performs processing to acquire (C₁+C₂), which is a value of a sub-calculation result for the label “a”, from the dictionary calculation unit 24 and return this value to the node with label “1” at the second level. Note that the sub-calculation result by the dictionary calculation unit 24 is stored in the dictionary calculation result storing unit 25. The node with label “1” at the second level adds a result of multiplying the value A₁ sent from a parent node by (C₁+C₂) sent from a child node to P₁, which is the element corresponding to the index indicated by this node. To be specific, the compressed CSF calculation unit 26 calculates P₁+=A₁(C₁+C₂). Note that the initial value of P₁ is 0.

The calculation of Expression (6) is achieved by performing such processing on all nodes in the same manner. In the case (3), the number of computations is reduced because a result of the dictionary calculation result storing unit 25 can be used just like in the case (1).

The second example embodiment is described above. Note that the calculation specifying unit 23, the dictionary calculation unit 24, the dictionary calculation result storing unit 25, and the compressed CSF calculation unit 26 may be referred to as a multiplication unit. Specifically, in the information processing device 2 according to this example embodiment, the multiplication unit calculates the product of a tensor represented by compressed CSF data and (M−1) number of matrices based on the compressed CSF data, replacement rule data, and the (M−1) number of matrices. Thus, the information processing device 2 according to this example embodiment enables tensor-matrix multiplication of a compressed CSF and matrices. Further, particularly, this multiplication unit includes the dictionary calculation unit 24 (first calculation unit) that performs a specified calculation for calculating the product of a tensor and matrices by using replacement rule data and the dictionary calculation result storing unit 25 that stores the calculation result. This multiplication unit further includes the compressed CSF calculation unit (second calculation unit) that calculates the product of a tensor and matrices by using the calculation result stored in the dictionary calculation result storing unit 25. This configuration enables the reduction of computational costs. Specifically, by storing a sub-calculation result for a node replaced in the compression of the CSF in the dictionary calculation result storing unit 25, the number of computations of the sub-calculation is reduced, which enables the reduction of computational costs. Therefore, according to this example embodiment, the computational costs of the product of a large-scale tensor and matrices are reduced.

Note that the information processing device 2 may further include a learning unit that performs machine learning by using multiplication results of a tensor and matrices calculated by the multiplication unit or may include a data analysis unit that performs data analysis using multiplication results of a tensor and matrices calculated by the multiplication unit.

While the invention has been particularly shown and described with reference to example embodiments thereof, the invention is not limited to these example embodiments. It will be understood by those of ordinary skill in the art that various changes in form and details may be made therein without departing from the spirit and scope of the present invention as defined by the claims.

### REFERENCE SIGNS LIST

1 INFORMATION PROCESSING DEVICE
2 INFORMATION PROCESSING DEVICE
11 CSF DESIGN UNIT
12 CSF CONSTRUCTION UNIT
13 CSF COMPRESSION UNIT
21 COMPRESSED TENSOR ACQUISITION UNIT
22 MATRIX ACQUISITION UNIT
23 CALCULATION SPECIFYING UNIT
24 DICTIONARY CALCULATION UNIT
25 DICTIONARY CALCULATION RESULT STORING UNIT
26 COMPRESSED CSF CALCULATION UNIT
50 PROCESSOR
51 MEMORY
52 STORAGE DEVICE

What is claimed is:

1. An information processing device comprising:
at least one memory storing program instructions; and
at least one processor configured to execute the instructions stored in the memory to:
set an order of axes of a tensor of M (M is a natural number of 3 or more) or higher order in order to convert a tensor into data in CSF (Compressed Sparse Fiber) representation;
convert the tensor of M or higher order into data in CSF representation according to the setting; and
to compress the data in CSF representation by replacing an overlapping structure appearing in the data in CSF representation with an alternative structure representing the overlapping structure, and output compressed CSF data being a compressed version of the data in CSF representation and replacement rule data being data indicating a replacement rule.

2. The information processing device according to claim 1, wherein the processor is further configured to execute the instructions to:
acquire the compressed CSF data and the replacement rule data;
acquire (M−1) number of matrices; and
calculate a product of a tensor represented by the compressed CSF data and the (M−1) number of matrices based on the compressed CSF data and the replacement rule data and the (M−1) number of matrices.

3. The information processing device according to claim 2, wherein the processor is further configured to execute the instructions to:
perform a specified calculation for calculating a product of the tensor and the matrices by using the replacement rule data;
store a calculation result of the specified calculation; and
calculate a product of the tensor and the matrices by using the calculation result.

4. The information processing device according to claim 1, wherein the processor is further configured to execute the instructions to compresses the data in CSF representation by grammar compression, and outputs the compressed CSF data and a dictionary being data representing the replacement rule.

5. The information processing device according to claim 1, wherein the tensor is a knowledge graph.

6. A tensor compression method comprising:
setting an order of axes of a tensor of M (M is a natural number of 3 or more) or higher order in order to convert a tensor into data in CSF (Compressed Sparse Fiber) representation;
converting the tensor of M or higher order into data in CSF representation according to the setting; and
compressing the data in CSF representation by replacing an overlapping structure appearing in the data in CSF representation with an alternative structure representing the overlapping structure, and outputting compressed CSF data being a compressed version of the data in CSF representation and replacement rule data being data indicating a replacement rule.

7. A non-transitory computer readable medium storing a program causing a computer to perform:
a CSF setting step of setting an order of axes of a tensor of M (M is a natural number of 3 or more) or higher order in order to convert a tensor into data in CSF (Compressed Sparse Fiber) representation;
a CSF construction step of converting the tensor of M or higher order into data in CSF representation according to setting in the CSF setting step; and
a CSF compression step of compressing the data in CSF representation by replacing an overlapping structure appearing in the data in CSF representation with an alternative structure representing the overlapping structure, and outputting compressed CSF data being a compressed version of the data in CSF representation and replacement rule data being data indicating a replacement rule.
